(19) United States
(12) Patent Application Publication
(10) Pub. No.: US 2003/0107663 A1
(43) Pub. Date: Jun. 12, 2003

(54) Complementary metal-oxide-semiconductor image sensor sturcture of mixed integration area and potential reading method employing the same

(76) Inventors: Hsiu-Yu Cheng, Kaohsiung Hsien (TW); Ya-Chin King, Chungli (TW)

Correspondence Address: J.C. Patents, Inc., 4 Venture, Suite 250, Irvine, CA, 92618, US

(21) Appl. No.: 10/068,250

(22) Filed: Feb. 6, 2002

(30) Foreign Application Priority Data
Dec. 7, 2001 (TW) 90130290

(51) Int. Cl. H04N 3/14; H01L 31/062

(52) U.S. Cl. 348/294; 257/290

(57) ABSTRACT

The present invention provides a complementary metal-oxide-semiconductor (CMOS) image sensor structure and the potential reading method employing the same. The integration area composed of the photo diode and the photo gate is applied to receive the light emitted from the light source. The sensitivity is changed via the operation of controlling the gate voltage of the photo gate. Moreover, the variance of the potential is read many times. The characteristic of the potentials under different conditions in different times having the same dark current and fixed pattern noise is utilized. The dark current and the fixed pattern noise can be eliminated by calculating their difference. Higher sensitivity in low illumination and lower sensitivity in high illumination can be obtained by calculating their summation, so as to increase the dynamic range.

### CROSS-REFERENCE TO RELATED APPLICATION

This application claims the priority benefit of Taiwan application serial no. 90130290, filed Dec. 7, 2001.

### BACKGROUND OF THE INVENTION

1. Field of Invention

The present invention generally relates to a complementary metal-oxide-semiconductor (CMOS) image sensor structure and the potential reading method employing the same, and more particularly, to a CMOS image sensor structure of the mixed integration area and the potential reading method employing the same.

2. Description of Related Art

The image has always been the easiest information representation method for people to receive information. Because of this, people have dedicated themselves to the study of image observation and image storing topics. Thus, the devices and the equipment related to the image are quite abundant and versatile, for example the color palm-coder, the surveillance black-white camera, the digital camera, the facsimile machine, and the medical sensor, . . . , etc. All of this image processing equipment unavoidably applies the image sensor element. Since the CMOS image sensor has variant advantages, such as the high stabilization, high sensitivity, low operating voltage, low consuming power, high resistance, and is not interfered by high magnetic, thus, it is applied widely in this equipment. Whereas, if the CMOS image sensor is compared with the charge couple device (CCD), although the CMOS image sensor is cost effective, and easily integrated with other control circuits, such as the analog to digital circuit and the digital signal processing circuit on a single chip, to achieve the objective of the System On a Chip (SOC), the CMOS image sensor has higher dark current, and thus can not be applied in the low illumination environment, and can neither have a very long exposure time.

### SUMMARY OF THE INVENTION

In the view of this, the present invention provides a CMOS image sensor structure of mixed integration area and the potential reading method employing the same to clear its dark current and fixed pattern noise. The CMOS image sensor structure and the method employing the same has higher sensitivity in low illumination, and lower sensitivity in high illumination, so as to increase the dynamic range.

The present invention provides a CMOS image sensor structure of mixed integration area, wherein the CMOS image sensor structure of mixed integration area comprises an integration area, a reset transistor, a source-coupled transistor and an output selection transistor. The integration area is composed of the gate of the photo gate surrounded by the photo diode that is formed of the N type mixed surface on top of the P-well. The integration area is used to receive the light emitted from the light source, and react to the integration potential according to the intensity of the light source. The sensitivity can be changed by the operation of controlling the gate voltage of the photo gate. The reset transistor is used to reset the integration potential to the reset level. The source-coupled transistor is used to provide the output current of the integration potential to read the integration potential. The output selection transistor is used to select whether to read the integration potential. Each reset transistor, source-coupled transistor and output selection transistor is an N-MOS transistor.

The present invention further provides a first potential reading method of the CMOS image sensor of mixed integration area, wherein the image sensor at least comprises an integration area and a reset transistor. The integration area is composed of the photo diode and the photo gate and is used to receive the light emitted from the light source, and reacts to the integration potential according to the intensity of the light source. The sensitivity can be changed by the operation of controlling the gate voltage of the photo gate. The reset transistor is used to reset the integration potential to the reset level. The potential reading method comprises the steps of: at first, electrically conducting the reset transistor to reset the integration potential to the reset level; then, closing the reset transistor; afterwards, applying voltage to the photo gate to activate the operation of the photo gate; again, reading the integration potential when the photo diode and the photo gate cooperate together; once again, electrically conducting the reset transistor to reset the integration potential to the reset level; then, closing the reset transistor; again, reading the integration potential when the photo diode operates individually; finally, reading the difference value between the integration potentials when the photo diode operates independently and the integration potential when the photo diode and the photo gate cooperate together to clear its dark current and the fixed pattern noise.

The present invention further provides a second potential reading method of the CMOS image sensor of the mixed integration area, wherein the image sensor at least comprises an integration area and a reset transistor. The integration area is composed of the photo diode and the photo gate and is used to receive the light emitted from the light source, and reacts to the integration potential according to the intensity of the light source. The sensitivity can be changed by the operation of controlling the gate voltage of the photo gate. The reset transistor is used to reset the integration potential to the reset level. The potential reading method comprises the steps of: at first, electrically conducting the reset transistor to reset the integration potential to the reset level; then, closing the reset transistor and reading the reset potential; then, reading the integration potential when the photo diode operates independently; and calculating the difference between the reset level and the integration potential when the photo diode operates individually and use it as the first result value; then, applying the voltage to the photo gate to activate the operation of the photo gate; again, reading the integration potential when the photo diode and the photo gate cooperate together; afterwards, calculating the difference between the reset level and the integration potential when the photo diode and the photo gate cooperate together and using it as the second result value; finally, calculating the summation of the first result value and the second result value to provide higher sensitivity in the low illumination, and lower sensitivity in high illumination, so as to increase the dynamic range.

As shown by the description above, by applying a CMOS image sensor structure of mixed integration area of the present invention, and combining it with the first potential reading method of the CMOS image sensor of mixed integration area provided by the present invention, since the integration potentials of both readings contain the same dark current and fixed pattern noise, by calculating the difference between the integration potentials the dark current and fixed pattern noise therein is able to be completely eliminated. Furthermore, if the second potential reading method of the CMOS image sensor of mixed integration area provided by the present invention is combined, the characteristic of the integration potential being saturated in high illumination when the photo diode and the photo gate cooperate together is utilized. Adding the integration potentials of two readings is able to provide higher sensitivity in low illumination, and lower sensitivity in high illumination, so as to increase the dynamic range.

### BRIEF DESCRIPTION OF THE DRAWINGS

The accompanying drawings are included to provide a further understanding of the invention, and are incorporated in and constitute a part of this specification. The drawings illustrate embodiments of the invention, and together with the description, serve to explain the principles of the invention. In the drawings,

FIG. 1A schematically shows a structure of a conventional photo diode CMOS image sensor;

FIG. 1B schematically shows a structure of a conventional photo gate CMOS image sensor;

FIG. 2 schematically shows a structure of the CMOS image sensor of the mixed integration area of the preferred embodiment according to the present invention;

FIG. 3A schematically shows the reading circuit diagram of the first potential reading method of the CMOS image sensor of mixed integration area of the preferred embodiment according to the present invention;

FIG. 3B schematically shows the reading clock sequence diagram of the first potential reading method of the CMOS image sensor of mixed integration area of the preferred embodiment according to the present invention;

FIG. 3C schematically shows the reading result graph of the first potential reading method of the CMOS image sensor of mixed integration area of the preferred embodiment according to the present invention;

FIG. 4A schematically shows the reading circuit diagram of the second potential reading method of the CMOS image sensor of mixed integration area of the preferred embodiment according to the present invention;

FIG. 4B schematically shows the reading clock sequence diagram of the second potential reading method of the CMOS image sensor of mixed integration area of the preferred embodiment according to the present invention;

FIG. 4C schematically shows the reading result graph of the second potential reading method of the CMOS image sensor of mixed integration area of the preferred embodiment according to the present invention.

### DESCRIPTION OF THE PREFERRED EMBODIMENTS

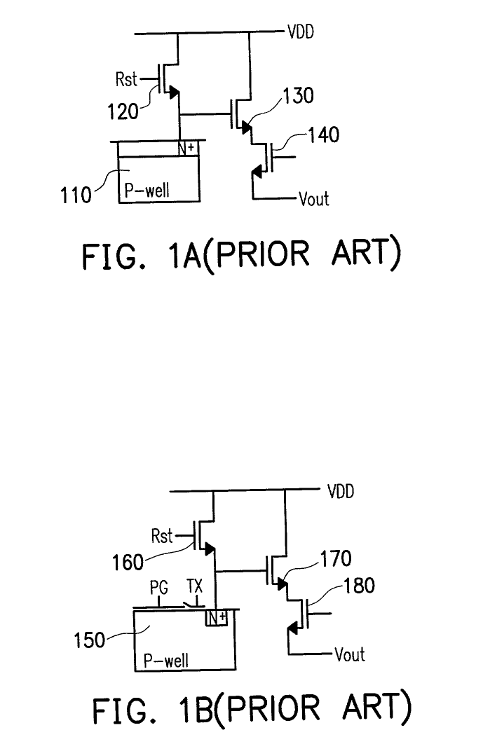

FIG. 1A schematically shows the structure of a conventional photo diode CMOS image sensor. FIG. 1B schematically shows the structure of a conventional photo gate CMOS image sensor. As shown in the diagrams, both structures of the conventional CMOS image sensor comprise an integration area 110 and 150, a reset transistor 120 and 160, a source-coupled transistor 130 and 170, and an output selection transistor 140 and 180. The reset transistor 120 and 160 is used to reset the integration potential of the integration area to the reset level. The source-coupled transistor 130 and 170 is used to provide the output current of the integration potential so as to read the integration potential. The output selection transistor 140 and 180 is used to select whether to read the integration potential. Whereas, the difference between them is that the integration area 110 of the photo diode CMOS image sensor is a photo diode, and the integration area 150 of the photo gate CMOS image sensor is a photo gate. Although both image sensors have their own pros and cons, neither of them can eliminate its dark current.

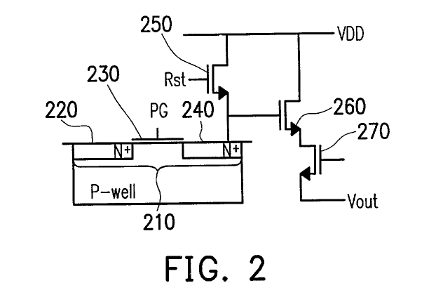

FIG. 2 schematically shows a structure of the CMOS image sensor of mixed integration area of a preferred embodiment according to the present invention. As shown in the diagram, the structure of the CMOS image sensor of mixed integration area similarly comprises an integration area 210, a reset transistor 250, a source-coupled transistor 260, and an output selection transistor 270. The integration area 210 is composed of the gate of the photo gate 230 surrounded by the photo diode 220 and 240 that is formed of the N type mixed surface on top of the P-well. The integration area is used to receive the light emitted from the light source, and reacts to the integration potential according to the intensity of the light source. The sensitivity can be changed by the operation of controlling the gate voltage of the photo gate 230. Similarly, the reset transistor 250 is used to reset the integration potential to the reset level. The source-coupled transistor 260 is used to provide the output current of the integration potential to read the integration potential. The output selection transistor 270 is used to select whether to read the integration potential. Each reset transistor 250, source-coupled transistor 260 and output selection transistor 270 is an N-MOS transistor.

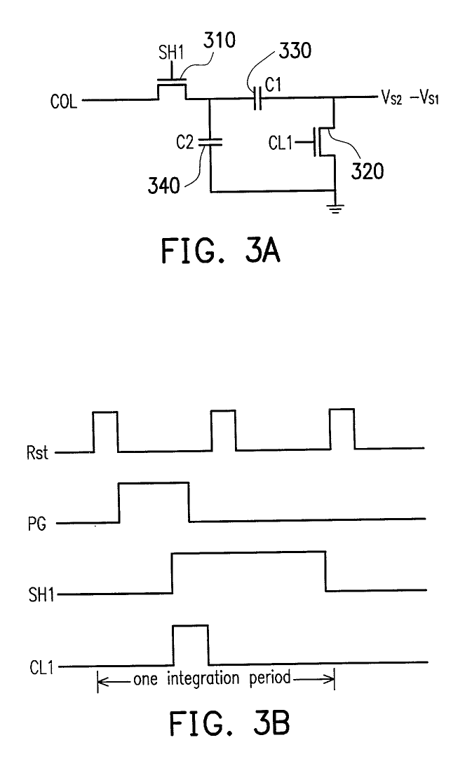

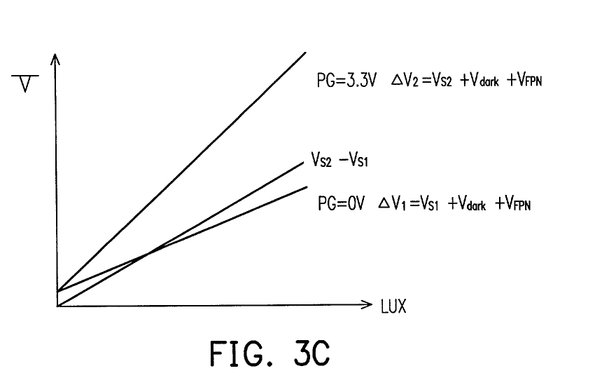

FIG. 3A schematically shows the reading circuit diagram of the first potential reading method of the CMOS image sensor of mixed integration area of a preferred embodiment according to the present invention. FIG. 3B schematically shows its reading clock sequence diagram. FIG. 3C schematically shows its reading result graph. As shown in the reading clock sequence in FIG. 3B, there are two reset operations in one integration period. Wherein, in one reset operation, the voltage is not applied to the photo gate 230, thus the photo gate 230 is deactivated, so as to obtain an integration potential difference of the lower sensitivity ΔV₁=Vᵣₑₛ−Vₒᵤₜ₁=Vₛ₁+V_{dark}+V_{FPN}, the integration potential will include the dark current V_{dark} and the fixed pattern noise V_{FPN} In the other reset operation, voltage 3.3 V is applied to the photo gate 230 to have it operate normally, so as to obtain an integration potential difference of the higher sensitivity ΔV₂=Vᵣₑₛ−Vₒᵤₜ₂=Vₛ₂+V_{dark}+V_{FPN}. This integration potential also includes the dark current V_{dark} and the fixed pattern noise V_{FPN}. Thus, it is known that the dark current V_{dark} and the fixed pattern noise V_{FPN} herein can be completely eliminated as long as the difference value ΔV₂−ΔV₁=(Vᵣₑₛ−Vₒᵤₜ₂)−(Vᵣₑₛ−Vₒᵤₜ₁)=(Vₛ₂+V_{dark}+V_{FPN})−(Vₛ₁+V_{dark}+V_{FPN})=Vₛ₂−V_{S1} is read. Moreover, the correlated double sampling circuit as shown in the graph of FIG. 3C does not have to be changed. The operation principle is that after the first reset operation, the voltage is applied to the photo gate to activate the operation of the photo gate. The transistor SH1 310 and the transistor CL1 320 are electrically conducted before the next reset operation. The transistor CL1 320 is subsequently closed so the stride voltage of the capacitor C1 330 Vₒᵤₜ₂=Vᵣₑₛ−(Vₛ₂+V_{dark}+V_{FPN}). After the next reset operation, the voltage is not applied to the photo gate, thus the operation of the photo gate is deactivated. Furthermore, the transistor SH1 310 is closed before the next reset operation, so the stride voltage of the capacitor C2 340 Vₒᵤₜ₁=Vᵣₑₛ−(Vₛ₁+V_{dark}+V_{FPN}) The output physically detected is the stride voltage of the capacitor C2 340 subtracts the stride voltage of the capacitor C1 330, Vₒᵤₜ₁−Vₒᵤₜ₂=(Vᵣₑₛ−(Vₛ₁+V_{dark}+V_{FPN}))−(Vᵣₑₛ−Vₛ₂+V_{dark}+V_{FPN}))=Vₛ₂−Vₛ₁. This is the result value mentioned above.

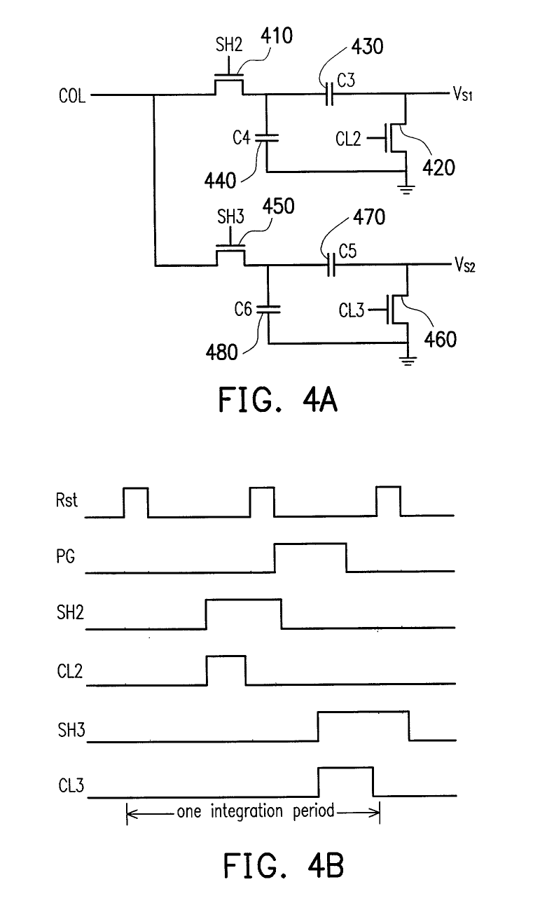

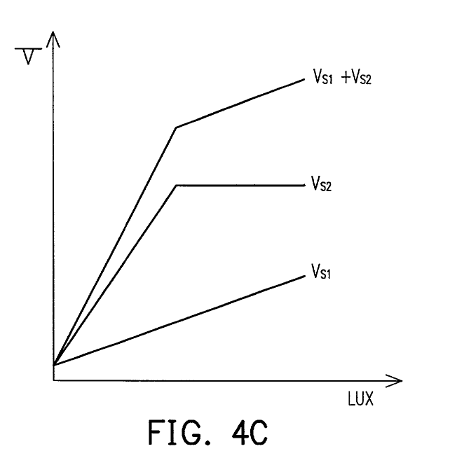

FIG. 4A schematically shows the reading circuit diagram of the second potential reading method of the CMOS image sensor of mixed integration area of a preferred embodiment according to the present invention. FIG. 4B schematically shows its reading clock sequence diagram. FIG. 4C schematically shows its reading result graph. As known from the reading clock sequence in FIG. 4B, there are two reset operations in one integration period. In one reset operation, the voltage is not applied to the photo gate 230, thus the photo gate 230 is deactivated, so as to obtain an integration potential difference of the lower sensitivity ΔV₁=Vᵣₑₛ−Vₒᵤₜ₁=Vₛ₁. In the other reset operation, voltage 3.3 V is applied to the photo gate 230 to have it operate normally, so as to obtain an integration potential difference of the higher sensitivity ΔV₂=Vᵣₑₛ−Vₒᵤₜ₂=Vₛ₂. Since this integration potential has higher sensitivity, when the light source has higher illumination, the integration potential is reduced to 0V from the reset level, thus the saturation situation occurs. Therefore, the dynamic range is limited by the reset level. In order to improve the limitation of the dynamic range, it is required to calculate the summation of Vₛ₁+Vₛ₂ as shown in FIG. 4C, so as to obtain the characteristic of having higher sensitivity in low illumination, and having lower sensitivity in high illumination. This method cannot utilize the original correlated double sampling circuit, thus the change as shown in FIG. 4A is required. The operation principle is that the transistor SH2 410 and the transistor CL2 420 are electrically conducted after the first reset operation and before the next reset operation. The transistor CL2 420 is subsequently closed so the stride voltage of the capacitor C3 430 is Vₒᵤₜ₁=Vᵣₑₛ−Vₛ₁. After the next reset operation, the transistor SH2 410 is closed, so the stride voltage of the capacitor C4 440 is Vᵣₑₛ. The output physically detected is the stride voltage of the capacitor C4 440 subtracts the stride voltage of the capacitor C3 430 Vᵣₑₛ−(Vᵣₑₛ−Vₛ₁)=Vₛ₁. At this moment, the voltage is applied to the photo gate to activate the operation of the photo gate. The transistor SH3 450 and the transistor CL3 460 are electrically conducted before the next reset operation. Then, the transistor CL3 460 is closed, so the stride voltage of the capacitor C5 470 Vₒᵤₜ₂=Vᵣₑₛ−Vₛ₂. The transistor SH3 450 is closed after the next reset operation, so the stride voltage of the capacitor C6 480 is Vᵣₑₛ. Therefore, the output physically detected is the stride voltage of the capacitor C6 480 subtracts the stride voltage of the capacitor C5 470 Vᵣₑₛ−(Vᵣₑₛ−Vₛ₂)=Vₛ₂. The expected result can be obtained from the summation of them.

As shown in the description above, by applying a CMOS image sensor structure of mixed integration area of the present embodiment, combined with the first potential reading method of the CMOS image sensor of mixed integration area of the present embodiment, since the integration potentials of the two readings contain the same dark current and fixed pattern noise, by calculating the difference between the integration potentials, the dark current and fixed pattern noise therein is able to be completely eliminated. Furthermore, if the second potential reading method of the CMOS image sensor of mixed integration area of the present embodiment is used the characteristic that the integration potential is saturated in the high illumination when the photo diode and the photo gate cooperate together is utilized. Adding the integration potentials of the two readings can provide higher sensitivity in low illumination, and lower sensitivity in high illumination, so as to increase the dynamic range.

Although the invention has been described with reference to a particular embodiment thereof, it will be apparent to one of the ordinary skill in the art that modifications to the described embodiment may be made without departing from the spirit of the invention. Accordingly, the scope of the invention will be defined by the attached claims not by the above detailed description.

What is claimed is:

1. A CMOS image sensor structure of the mixed integration area comprising:
an integration area, wherein, the integration area is used to receive a light emitted from a light source, and reacts to an integration potential according to the intensity of the light source, wherein, the integration is composed of a photo diode and a photo gate;
a reset transistor, wherein the reset transistor is used to reset the integration potential to the reset level;
a source-coupled transistor, wherein the source-coupled transistor is used to provide the output current of the integration potential to read the integration potential; and
an output selection transistor, wherein the output selection transistor is used to select whether to read the integration potential.

2. The CMOS image sensor structure of claim 1, wherein, the integration area is composed of the gate of the photo gate surrounded by the photo diode that is formed of the N type mixed surface on top of the P-well.

3. The CMOS image sensor structure of claim 2, wherein the reset transistor is an N-MOS transistor.

4. The CMOS image sensor structure of claim 2, wherein the source-coupled transistor is an N-MOS transistor.

5. The CMOS image sensor structure of claim 2, wherein the output selection transistor is an N-MOS transistor.

6. A potential reading method of the CMOS image sensor of the mixed integration area, the image sensor at least comprising an integration area and a reset transistor, wherein, the integration area is used to receive a light emitted from a light source, and reacts to an integration potential according to the intensity of the light source, wherein, the integration area is composed of a photo diode and a photo gate; the reset transistor is used to reset the integration potential to a reset level, the method comprising the steps of:
electrically conducting the reset transistor to reset the integration potential to the reset level;
closing the reset transistor;
reading the integration potential when the photo diode is operating individually;
applying the voltage to the photo gate to activate the operation of the photo gate;
reading the integration potential when the photo diode and the photo gate are cooperating together; and
calculating the difference value between the integration potential when the photo diode is operating individually and the integration potential when the photo diode and the photo gate are cooperating together.

7. A potential reading method of the CMOS image sensor of mixed integration area, the image sensor at least comprising an integration area and a reset transistor, wherein, the integration area is used to receive a light emitted from a light source, and reacts to an integration potential according to the intensity of the light source, wherein, the integration area is composed of a photo diode and a photo gate, and the reset transistor is used to reset the integration potential to a reset level, the method comprising the steps of:
electrically conducting the reset transistor to reset the integration potential to the reset level;
closing the reset transistor and reading the reset level;
reading the integration potential when the photo diode is operating individually;
calculating the difference between the reset level and the integration potential when the photo diode is operating individually, and using it as a first result value;
applying the voltage to the photo gate to activate the operation of the photo gate;
reading the integration potential when the photo diode and the photo gate are cooperating together;
calculating the difference between the reset level and the integration potential when the photo diode and the photo gate are cooperating together, and using it as a second result value; and
calculating the summation of the first result value and the second result value.
